(19) United States
(12) Patent Application Publication
(10) Pub. No.: US 2003/0067048 A1
(43) Pub. Date: Apr. 10, 2003

(54) Integrated circuit device

(76) Inventors: Wei-Feng Lin, Hsinchu (TW); Chung-Ju Wu, Kaohsiung (TW); Kuei-Chen Liang, Hsinchu (TW)

Correspondence Address: BIRCH STEWART KOLASCH & BIRCH, PO BOX 747, FALLS CHURCH, VA, 22040-0747, US

(21) Appl. No.: 10/212,111

(22) Filed: Aug. 6, 2002

(30) Foreign Application Priority Data
Oct. 5, 2001 (TW) 90124650

(51) Int. Cl. H01L 31/00

(52) U.S. Cl. 257/459

(57) ABSTRACT

An integrated circuit device. The integrated circuit device comprises a chip having a plurality of ground pads and power pads, a substrate having a ground ring and a power ring, and a plurality of first and second bonding wires electrically connecting the ground and power pads to the ground and power ring, wherein the ground pads are arranged closely in a first group and the power pads are arranged closely in a second group, thereby separating the first and second bonding wires from each other.

### BACKGROUND OF THE INVENTION

1. Field of the Invention

The present invention relates to an integrated circuit device, particularly to designs of a circuit substrate and pads on a chip, which results a high product yield.

2. Description of the Prior Art

FIG. 1 is a diagram showing a portion of a conventional circuit substrate 11. A chip 12 is mounted on the circuit substrate 11. The substrate 11 comprises a ground ring 111, power ring 112, signal fingers 113, and solder mask layers 114. The chip 12 has ground pads 121, power pads 122 and signal pads 123. There are bonding wires 131, 132 and 133 electrically connecting the ground pads 121, power pads 122 and signal pads 123 to the ground ring 111, power ring 112 and signal fingers 113 respectively. The chip 12 receives a ground and power supply voltage through the ground pads 121 and power pads 122, and receives or outputs signals through signal pads 123.

In the previously described prior art, the ground pads 121, power pads 122 and signal pads 123 are randomly arranged on the chip 12. As a result, that the bonding wires 131, 132 and 133 are also randomly arranged and close to each other.

In order to prevent improper contact of the bonding wires carrying different signals or voltages when molding, two adjacent bonding wires must have different curvatures and heights. Therefore, the distance between the ground ring and power ring must be large enough. However, the long distance between the ground and power ring leads to a high impedance, which degrades the electrical performance of the circuit substrate.

### SUMMARY OF THE INVENTION

Therefore, the object of the present invention is to provide an integrated circuit device wherein the bonding wire curvatures and heights are the same.

The present invention provides an integrated circuit device. The integrated circuit device comprises a chip having a plurality of ground pads and power pads, a substrate having a ground ring and a power ring, and a plurality of first and second bonding wires electrically connecting the ground and power pads to the ground and power ring, wherein the ground pads are arranged closely in a first group and the power pads are arranged closely in a second group, the first group being spared apart from the second group, thereby separating the first and second bonding wires from each other.

Thus, in the invention, the ground pads, power pads and signal pads are arranged closely in different groups. As a result, any two adjacent bonding wires carry the same voltage or signal. There is no impact on the circuit operation even if two adjacent bonding wires contact each other when molding.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 is a diagram showing a portion of a conventional circuit substrate.

FIG. 2A is a diagram showing a portion of an integrated circuit device according to one embodiment of the invention.

FIG. 2B is a diagram showing a cross section of the integrated circuit device in FIG. 2A.

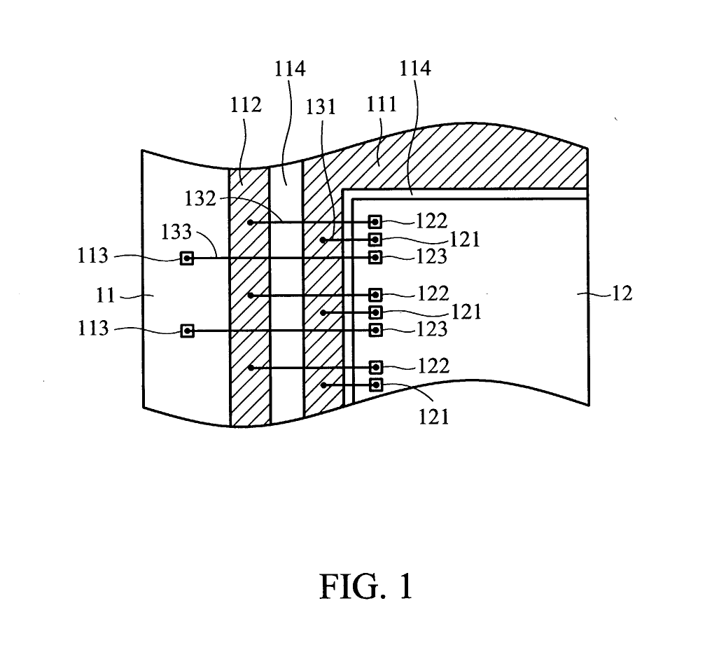

### DETAILED DESCRIPTION OF THE INVENTION

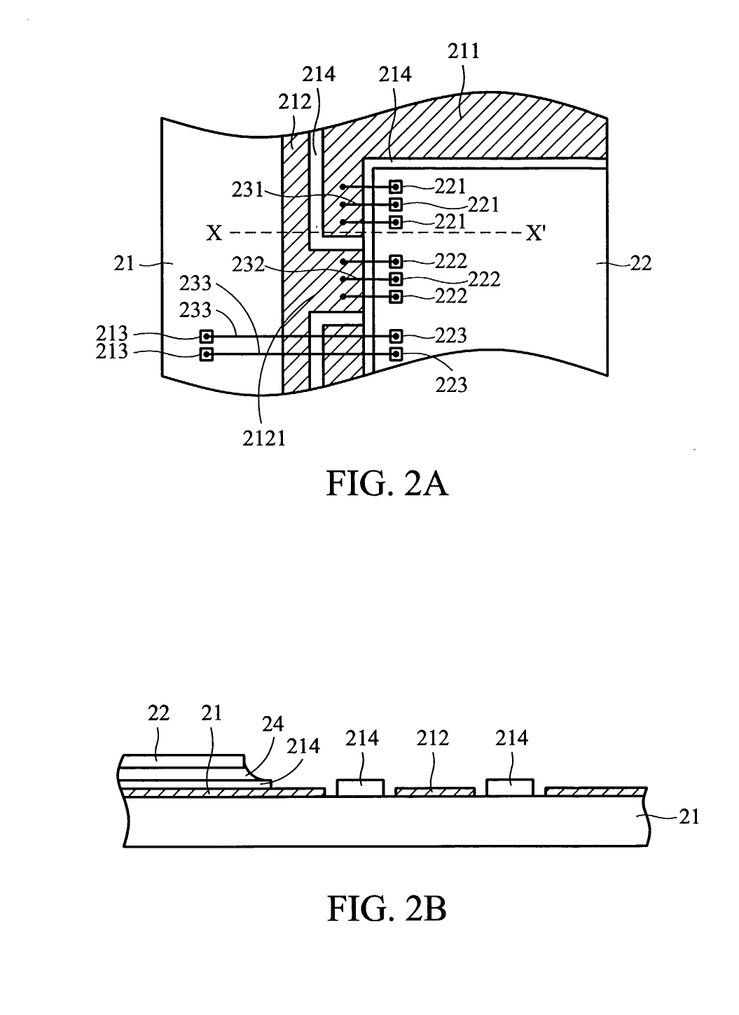

FIG. 2 is a diagram showing a portion of an integrated circuit device according to one embodiment of the invention. The integrated circuit device comprises a chip 22 mounted on a circuit substrate 21, a ground ring 211, power ring 212 and signal fingers 213 on the circuit substrate 21, ground pads 221, power pads 222 and signal pads 223 on the chip 22, boding wires 231, 232 and 233, and solder mask layers 214. The boding wires 231, 232 and 233 electrically connect the ground pads 221, power pads 222 and signal pads 223 to the ground ring 211, power ring 212 and signal fingers 213 respectively. The chip 22 receives a ground and power supply voltage through the ground pads 221 and power pads 222, and receives or outputs signals through signal pads 223.

The power ring 212 has a protrusion 2121 where the boding wires 232 are connected. The ground ring 211 has an indentation conforming with the protrusion 2121 of the power ring 212. This shortens the length of the bonding wires 232, which is advantageous to the electrical performance of the integrated circuit device.

FIG. 2B is a diagram showing a cross section of the integrated circuit device in FIG. 2A. The same elements in FIGS. 2A and 2B refer to the same symbol. As previously described, the circuit substrate 21 has the ground ring 211, power ring 212. The solder mask layer 214 is formed between the chip 22 and the substrate 21, and between the ground and power ring 211 and 212. An epoxy layer 24 is formed between the solder mask layer 214 and the chip 22 to fix the chip 22 onto the solder mask layer 214.

In the embodiment, the ground pads 221, power pads 222 and signal pads 223 are closely arranged in different groups on the chip 22. As a result, the bonding wires 231, 232 and 233 are also closely arranged in three separated groups. The boding wires for different purposes are separated from each other.

Since the bonding wires 231 carrying the same ground voltage, there is no impact on the circuit operation even if the bonding wires 231 contact each other when molding. Similarly, the bonding wires 232 carrying the same power supply voltage, there is no impact on the circuit operation even if the bonding wires 232 contact each other when molding. Thus, the bonding wires 231, 232 and 233 can have the same curvature and height. Additionally, the protrusion 2121 shortens the length of the bonding wires 232, thereby achieving a better performance than conventional longer bonding wires.

In conclusion, the ground pads, power pads and signal pads are arranged closely in different groups. As a result, that any two adjacent bonding wires carry the same voltage or signal. There is no impact on the circuit operation even if two adjacent bonding wires contact each other when molding.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An integrated circuit device comprising:
a chip having a plurality of ground pads and power pads;
a substrate having a ground ring and a power ring; and
a plurality of first and second bonding wires electrically connecting the ground and power pads to the ground and power ring;
wherein the ground pads are arranged closely in a first group and the power pads are arranged closely in a second group, thereby separating the first and second bonding wires from each other.

2. The integrated circuit device as claimed in claim 1 further comprising a plurality of third bonding wires, wherein the substrate and chip further comprise a plurality of signal fingers and pads respectively, the third bonding wires electrically connecting the signal pads to the signal fingers, and the signal pads are arranged closely in a third group, the first group being spared apart from the second group, thereby separating the third bonding wires from the first and second boding wires.

3. The integrated circuit device as claimed in claim 1, wherein the power ring has a protrusion where the second boding wires are connected.

4. The integrated circuit device as claimed in claim 3, wherein the ground ring has an indentation conforming with the protrusion of the power ring.

5. The integrated circuit device as claimed in claim 1 further comprising a solder mask layer between the chip and the substrate, and between the ground and power ring.

6. The integrated circuit device as claimed in claim 5 further comprising an epoxy layer between the solder mask layer and the chip.
